(19) United States
(12) Patent Application Publication
(10) Pub. No.: US 2025/0059072 A1
(43) Pub. Date: Feb. 20, 2025

(54) WATER TREATMENT SYSTEM

(71) Applicant: KYUNGDONG NAVIEN CO., LTD., Pyeongtaek-si, Gyeonggi-do (KR)

(72) Inventors: Soo Young Lee, Seoul (KR); Chan Woo Lee, Seoul (KR); Ji Hyung Yoon, Seoul (KR); Bum Seup Kim, Seoul (KR)

(21) Appl. No.: 18/717,325

(22) PCT Filed: Dec. 1, 2022
(86) PCT No.: PCT/KR2022/019367

§ 371 Date: Jun. 6, 2024

(30) Foreign Application Priority Data
Dec. 16, 2021 (KR) 10-2021-0181023

(51) Int. Cl. C02F 1/469; C02F 1/00; C02F 1/46

(52) U.S. Cl. CPC C02F 1/4691; C02F 1/008; C02F 1/4602; C02F 2201/005; C02F 2303/16

(57) ABSTRACT

The present invention relates to a water treatment system for removing at least some of ionic materials included in source water to provide soft water comprising less ionic materials than the source water to a demand source. The water treatment system may comprise: a filter module provided so as to remove at least some of ionic materials included in source water by means of an electrical force to discharge soft water; a supply channel provided so as to supply the source water to the filter module; a discharge channel provided so as to guide the soft water discharged from the filter module to a demand source; a circulation channel branched from the supply channel; a reclaim channel branched from the discharge channel; a connection channel branched from the reclaim channel and connected to the circulation channel; and a descaling part connected to the connection channel and provided so as to provide a descaling material for removing scale to the inside of the connection channel.

### TECHNICAL FIELD

The present disclosure relates to a water treatment system.

### BACKGROUND ART

A water treatment system is a system that produces soft water from source water that is supplied from a water source and supplies it to a demand source. For example, in a points of entry (PoE) type water treatment system, the demand source may be a house, and the soft water delivered to the demand source may be delivered to faucets, shower heads, and the like that require use of water.

A filter module that turns source water into soft water by removing ionic materials from the source water cannot be used permanently, and even in the case of a filter module that may be used semi-permanently, a reclaiming operation of discharging the collected ionic materials has to be performed periodically to ensure smooth use.

When a reclaim operation is performed, the ionic materials may be discharged directly from the filter module, but the ionic materials may form scale in the filter module. When scale is formed, an interior of the filter module may be contaminated. When the scale covers the interior of the filter module, an area in the interior of the filter module that may absorb ions may be decreased, and thus, a performance of the filter module may be degraded. Because the scale includes particulate matters, it may not be discharged smoothly even while the reclaim operation is in progress.

Accordingly, to maintain the performance of the filter module, in addition to the reclaim operation, a separate descaling process is required to remove the scale formed in the filter module. Generally, for the descaling process, a method of filling the filter module with citric acid to remove scale and then discharging it is used.

However, in the case of an inlet, through which the citric acid enters the filter module, a scale removal effect is high, but as the descaling ability decreases while the citric acid passes through the filter module, the scale removal effect is low at an outlet, through which the citric acid is discharged.

Meanwhile, scale may accumulate in a reclaim valve disposed in a reclaim channel for a reclaim operation and a pressure reducing ring in an interior of the reclaim channel. However, when the citric acid passes through the filter module and reaches the reclaim valve and the pressure reducing valve, the descaling ability decreases, and thus, the scale removal effect of the reclaim valve and the pressure reducing ring is low.

### DISCLOSURE

### Technical Problem

An aspect of the present disclosure provides a water treatment system with an increased scale removing effect of a filter module.

An aspect of the present disclosure also provides a water treatment system with an increased scale removing effect of a reclaim valve and a pressure reducing ring.

### Technical Solution

According to an aspect of the present disclosure, a water treatment system for removing at least some of ionic materials contained in source water and providing soft water containing less ionic materials than the source water to a demand source includes a filter module that removes at least some of the ionic materials contained in the source water based on an electrical force, and discharge the soft water, a supply channel that supplies the source water to the filter module, a discharge channel that guides the soft water discharged from the filter module to the demand source, a circulation channel branched from the supply channel, a reclaim channel branched from the discharge channel, a connection channel connecting the discharge channel and the circulation channel, and a descaling part connected to the connection channel, and that provides a descaling material for removing scale to an interior of connection channel.

In another example, the descaling part may include a descaling channel connected to the connection channel, a descaling module connected to a distal end of the descaling channel, and that provides the descaling material to the descaling channel, and a descaling pump disposed in the descaling channel, and that pumps the descaling material provided by the descaling module, to the connection channel through the descaling channel.

In another example, the water treatment system may further include a reclaim valve disposed in the reclaim channel, and that opens and closes the reclaim channel, and when a process of injecting the descaling material to the filter module to remove the scale in the filter module is a filter module injection process, in the filter module injection process, the descaling part may provide the descaling material when the reclaim valve opens the reclaim channel.

In another example, the water treatment system may further include a supply valve disposed in the supply channel, disposed on an upstream side of a point, at which the circulation channel is branched from the supply channel, and that opens and closes the supply channel, and a discharge valve disposed in the discharge channel, disposed on a downstream side of a point, at which the reclaim channel is branched from the discharge channel, and that opens and closes the discharge channel, and the descaling part may provide the descaling material when the supply valve closes the supply channel and the discharge valve closes the discharge channel.

In another example, the water treatment system may further include a circulation pump disposed in the circulation channel, disposed on an upstream side of a point, at which the circulation channel and the connection channel are connected to each other, and that pumps a fluid in the circulation channel to the connection channel.

In another example, when a process of cleaning the filter module by circulating the descaling material is a circulation process, in the circulation process, the descaling part may stop providing the descaling material, and the circulation pump may pump the descaling material in the circulation channel.

In another example, the water treatment system may further include a connection valve disposed in the connection channel, and that opens and closes the connection channel, and when a process of discharging the source water introduced through the supply channel, through the reclaim channel via the filter module is a module flushing process, in the module flushing process, the connection valve may close the connection channel.

In another example, the water treatment system may further include a circulation pump disposed in the circulation channel, disposed on an upstream side of a point, at which the circulation channel and the connection channel are connected to each other, and that pumps the fluid in the circulation channel to the connection channel, and when a process of flushing the circulation pump after the module flushing process is a pump flushing process, in the pump flushing process, the connection valve may open the connection channel, and the circulation pump may pump the fluid in the circulation channel to the connection channel.

In another example, the water treatment system may further include a supply valve disposed in the supply channel, disposed on an upstream side of a point, at which the circulation channel is branched from the supply channel, and that opens and closes the supply channel, and a discharge valve disposed in the discharge channel, disposed on a downstream side of a point, at which the reclaim channel is branched from the discharge channel, and that opens and closes the discharge channel, and when a process of introducing the source water into the circulation channel and discharging the source water to the reclaim channel after the pump flushing process is a discharge process, in the discharge process, the supply valve may open the supply channel, and the discharge valve may open the discharge channel.

In another example, the water treatment system may further include a reclaim valve disposed in the reclaim channel, and that opens and closes the reclaim channel, and when a process of injecting the descaling material to the reclaim channel to remove scale in the reclaim valve is a reclaim channel injection process, in the reclaim channel injection process, the descaling part may provide the descaling material when the reclaim valve opens the reclaim channel.

In another example, the reclaim channel may include a first reclaim line located on an upstream side of the reclaim valve, extending upward, and connected to the connection channel, a second reclaim line, one end of which is connected to a lower end of the first reclaim line, and in which the reclaim valve is disposed, and a third reclaim line located on a downstream side of the reclaim valve, connected to an opposite end of the second reclaim line, and extending upward.

In another example, the reclaim channel may further include a pressure reducing ring disposed at a boundary of the second reclaim line and the third reclaim line, and a size of an inlet of the pressure reducing ring may be smaller than a size of an outlet thereof.

In another example, the reclaim channel may further include a fourth reclaim line connected to an upper end of the third reclaim line, and extending to cross the third reclaim line, and in the reclaim channel injection process, the descaling material may be filled up to a reservoir boundary being a boundary of the third reclaim line and the fourth reclaim line.

In another example, the water treatment system may further include a fitting module connecting the circulation channel, the connection channel, and the descaling part, and the fitting module may include a first part extending downward, and connected to the connection channel, a second part having a shape extending from an upper end of the first part in a first direction being a direction crossing a downward direction and then extending downward, and connected to the descaling part, and a third part extending from the upper end of the first part in a second direction being an opposite direction to the first direction, and connected to the circulation channel.

In another example, the water treatment system may further include a reclaim valve disposed in the reclaim channel, and that opens and closes the reclaim channel, a supply valve disposed in the supply channel, disposed on an upstream side of a point, at which the circulation channel is branched from the supply channel, and that opens and closes the supply channel, a discharge valve disposed in the discharge channel, disposed on a downstream side of a point, at which the reclaim channel is branched from the discharge channel, and that opens and closes the discharge channel, a connection valve disposed in the connection channel, and that opens and closes the connection channel, a circulation pump disposed in the circulation channel, disposed on an upstream side of a point, at which the circulation channel and the connection channel are connected to each other, and that pumps the fluid in the circulation channel to the connection channel, and a controller that control the descaling part, the reclaim valve, the supply valve, the discharge valve, the connection valve, and the circulation pump.

In another example, when a process of injecting the descaling material into the filter module to remove the scale in the filter module is a filter module injection process, in the filter module injection process, the controller may control the reclaim valve to open the reclaim channel, control the supply valve to close the supply channel, control the discharge valve to close the discharge channel, control the connection valve to open the connection channel, and operate the descaling part to provide the descaling material to the filter module via the connection channel and the discharge channel.

In another example, when a process of removing the scale in the filter module by circulating the descaling material to the filter module is a circulation process, in the circulation process, the controller may control the reclaim valve to close the reclaim channel, control the supply valve to close the supply channel, control the discharge valve to close the discharge channel, control the connection valve to open the connection channel, stop an operation of the descaling part, and circulate the descaling material to the filter module by operating the circulation pump to pump the descaling material in the circulation channel.

In another example, when a process of discharging the source water introduced through the supply module, through the reclaim channel via the filter module is a module flushing process, in the module flushing process, the controller may control the reclaim valve to open the reclaim channel, control the supply valve to open the supply channel, control the discharge valve to close the discharge channel, control the connection valve to close the connection channel, stop an operation of the circulation pump, and discharge the source water introduced through the supply channel, via the filter module, the discharge channel, and the reclaim channel.

In another example, when a process of injecting the descaling material to the reclaim channel to remove the scale in the reclaim valve is a reclaim channel injection process, in the reclaim channel injection process, the controller may control the reclaim valve to open the reclaim channel, control the supply valve to close the supply channel, control the discharge valve to close the discharge channel, control the connection valve to open the connection channel, and operate the descaling part and provide the descaling material to the reclaim channel via the connection channel.

According to another aspect of the present disclosure, a water treatment system for removing at least some of ionic materials contained in source water and providing soft water containing less ionic materials than the source water to a demand source includes a filter module that removes at least some of the ionic materials contained in the source water based on an electrical force, and discharge the soft water, a supply channel that supplies the source water to the filter module, a discharge channel that guides the soft water discharged from the filter module to the demand source, a reclaim channel branched from the discharge channel, and a descaling part connected to the reclaim channel, and that provides a descaling material for removing scale to an interior of the reclaim channel.

In another example, the descaling part may include a descaling pump that pumps the descaling material, and when a direction, in which the soft water is discharged from the filter module is a forward direction and an opposite direction thereto is a reverse direction, the descaling pump may pump the descaling material such that the descaling material is introduced into the filter module in the reverse direction.

In another example, the water treatment system may further include a reclaim valve disposed in the reclaim channel, disposed on a downstream side of a point, at which the descaling part is connected to the reclaim channel, and that opens and closes the reclaim channel.

### Advantageous Effects

According to the present disclosure, the scale removing effect of the filter module may be increased by injecting the descaling material in the reverse direction of the filter module.

In addition, according to the present disclosure, the material for descaling may be stored in the reclaim channel, and thus, the scale removing effect of the reclaim valve and the pressure reducing ring may be increased.

### DESCRIPTION OF DRAWINGS

FIG. 1 is a water pipeline diagram of a water treatment system according to an embodiment of the present disclosure.

FIG. 2 is a conceptual view illustrating a principle of removing ionic materials in a CDI scheme.

FIG. 3 is a conceptual view illustrating a principle of reclaiming an electrode in a CDI scheme.

FIG. 4 conceptually illustrates a cross section of a reclaim channel.

FIG. 5 is a water pipeline diagram of a water treatment system according to another embodiment of the present disclosure.

FIG. 6 is a view illustrating a fitting module.

FIG. 7 is a view illustrating a filter module injection process.

FIG. 8 is a view illustrating a circulation process.

FIG. 9 is a view illustrating a module flushing process.

FIG. 10 is a view illustrating a pump flushing process.

FIG. 11 is a view illustrating a discharge process.

FIG. 12 is a view illustrating a reclaim channel injection process.

FIG. 13 is a view illustrating a standby process.

FIG. 14 is a view illustrating a flushing process.

### MODE FOR INVENTION

This application claims the benefit of priority to Korean Patent Application No. 10-2021-0181023, filed in the Korean Intellectual Property Office on Dec. 16, 2021, the entire contents of which are incorporated herein by reference.

Hereinafter, embodiments of the present disclosure will be described in detail with reference to the accompanying drawings. In adding reference numerals to the components of the drawings, it is noted that the same components are denoted by the same reference numerals even when they are drawn in different drawings. Furthermore, in describing the embodiments of the present disclosure, when it is determined that a detailed description of related known configurations and functions may hinder understanding of the embodiments of the present disclosure, a detailed description thereof will be omitted.

Meanwhile, in the present disclosure, the expressions, an upstream side and a downstream side may be based on a direction of a flow of a fluid. For example, when a fluid flows from a left side to a right side, the left side may correspond to an upstream side and the right side may correspond to a downstream side.

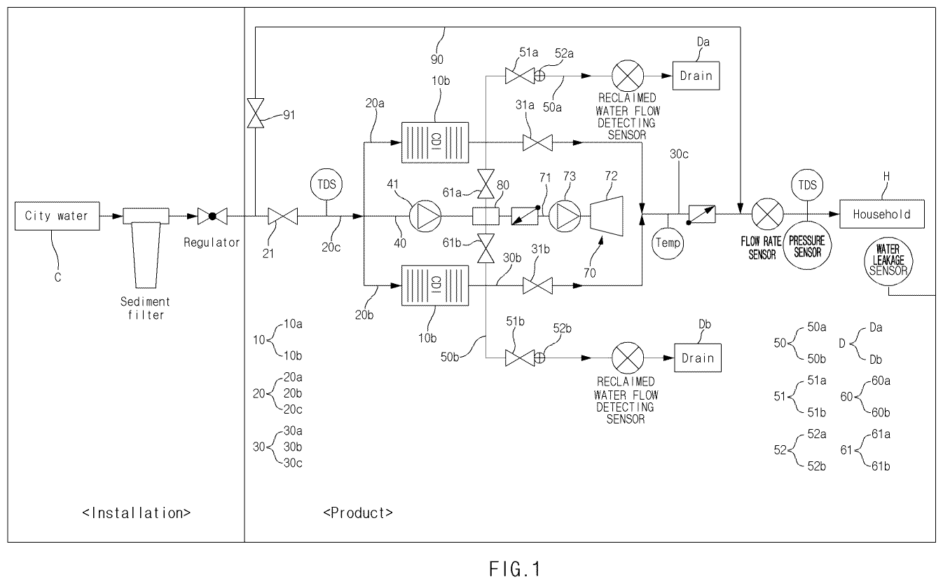

FIG. 1 is a water pipeline diagram of a water treatment system according to an embodiment of the present disclosure. The water treatment system according to an embodiment of the present disclosure relates to a water treatment system for remove at least some of the ionic materials contained in source water that is supplied from a water source “C” and providing soft water containing less ionic materials than the source water to a demand source “H”. Hereinafter, the basic components of the water treatment system will be described in detail with reference to FIG. 1.

### <Filter Module 10>

As illustrated in FIG. 1, a water treatment system according to an embodiment of the present disclosure may include a filter module 10. The filter module 10 may remove ionic materials from source water by using a capacitive deionization (CDI) scheme among electrical deionization schemes. The CDI scheme refers to a scheme of removing ions by using a principle that ions (or ionic materials) are adsorbed and desorbed from a surface of an electrode by an electrical force.

The filter module 10 may be provided with the source water delivered from the water source “C”, and the filter module 10 may remove at least some of the ionic materials contained in the provided source water based on an electrical force to produce and discharge soft water. Furthermore, the filter module 10 may generate and discharge the reclaimed water by sending out the ionic materials to the provided source water.

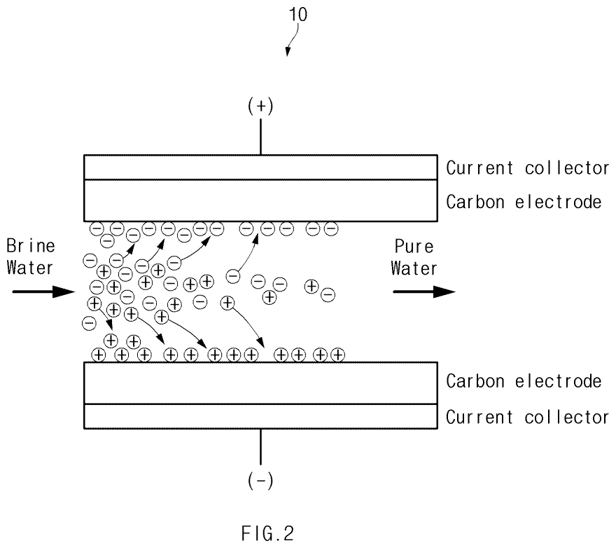

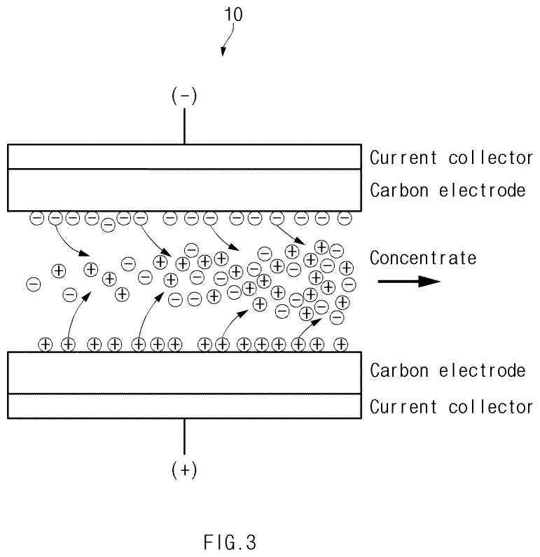

FIG. 2 is a conceptual view illustrating a principle of removing the ionic materials in the CDI scheme. FIG. 3 is a conceptual view illustrating a principle of reclaiming an electrode in the CDI scheme.

With further reference to FIGS. 2 and 3, a removal mode and a reclaim mode of the CDI scheme will be described. As illustrated in FIG. 2, when water containing ions passes between the electrodes while a voltage is applied to the electrodes, negative ions move to a positive electrode and positive ions move to a negative electrode. That is, adsorption occurs. The ions may be removed from the water through the adsorption. In this way, a mode, in which the filter module 10 removes ions (ionic materials) in the water that passes through the filter module 10 through the electrodes is called a removal mode.

However, an adsorption capacity of the electrodes is limited. Accordingly, when the adsorption continues, the electrodes reach a state, in which they may no longer adsorb ions. To prevent this, it is necessary to reclaim the electrodes by desorbing the ions adsorbed on the electrodes. For this purpose, as illustrated in FIG. 3, a voltage that is opposite to that in the removal mode may be applied to the electrodes, or no voltage may be applied. In this way, a mode, in which the filter module 10 reclaims the electrodes is called a reclaim mode. The reclaim mode may be performed before or after the removal mode.

Accordingly, for this operation, the filter module 10 may include electrodes. The filter module 10 may selectively perform any one of a removal mode, in which the ionic materials are removed by the electrical deionization scheme through the electrodes, or a reclaim mode, in which the electrodes are reclaimed. Accordingly, when source water is supplied to the filter module 10, in the removal mode, at least some of the ionic materials in the source water may be removed to generate soft water and be discharged from the filter module 10, and in the reclaim mode, the ionic materials contained in the electrodes are provided to the source water and the water with an increased content of the ionic materials may be discharged by the filter module 10.

### <Supply Channel 20>

As illustrated in FIG. 1, the water treatment system according to an embodiment of the present disclosure may include a supply channel 20. The supply channel 20 may be configured to supply the source water from the water source “C” to the filter module 10.

### <Supply Valve 21 and Other Components>

As illustrated in FIG. 1, the water treatment system according to an embodiment of the present disclosure may include a supply valve 21. The supply valve 21 may be disposed in the supply channel 20 and may be configured to open and close the supply channel 20. As illustrated in FIG. 1, the supply valve 21 may be disposed on an upstream side of a point, at which a circulation channel 40 that will be described later is branched from the supply channel 20. Furthermore, the supply channel 20 may include a precipitation sensor, a regulator, and a TDS sensor.

### <Discharge Channel 30>

As illustrated in FIG. 1, the water treatment system according to an embodiment of the present disclosure may include a discharge channel 30. The discharge channel 30 may be configured to guide the soft water that is discharged from the filter module 10 to the demand source “H”.

### <Discharge Valve 31 and Other Components>

As illustrated in FIG. 1, the water treatment system according to an embodiment of the present disclosure may include a discharge valve 31. The discharge valve 31 may be disposed in the discharge channel 30, and may be configured to open and close the discharge channel 30. Furthermore, the discharge channel 30 may include a temperature sensor, a flow rate sensor, a pressure sensor, and a TDS sensor.

### <Plurality of Filter Modules>

A plurality of filter modules 10 may be provided. As an example, as illustrated in FIG. 1, the filter module 10 may include a first filter module 10a and a second filter module 10b. However, this is only an example, and it is apparent that the number of the filter modules 10 may be changed in various ways depending on needs of the user.

In this case, the supply channel 20 may include a first supply channel 20a that is connected to the first filter module 10a and a second supply channel 20b that is connected to the second filter module 10b. Furthermore, the supply channel 20 may include a third supply channel 20c that is connected to the first supply channel 20a and the second supply channel 20b, and is connected to the water source “C”. However, it may also be possible to connect the first supply channel 20a and the second supply channel 20b to the water source “C” without the third supply channel 20c.

Furthermore, the discharge channel 30 may include a first discharge channel 30a that is connected to the first filter module 10a and a second discharge channel 30b that is connected to the second filter module 10b. Then, as illustrated in FIG. 1, a first discharge valve 31a may be disposed in the first discharge channel 30a, and a second discharge valve 31b may be disposed in the second discharge channel 30b. Furthermore, the discharge channel 30 may include a third discharge channel 30c that is connected to the first discharge channel 30a and the second discharge channel 30b, and is connected to the demand source “H”. However, it may also be possible to connect the first discharge channel 30a and the second discharge channel 30b to the demand source “H” without the third discharge channel 30c.

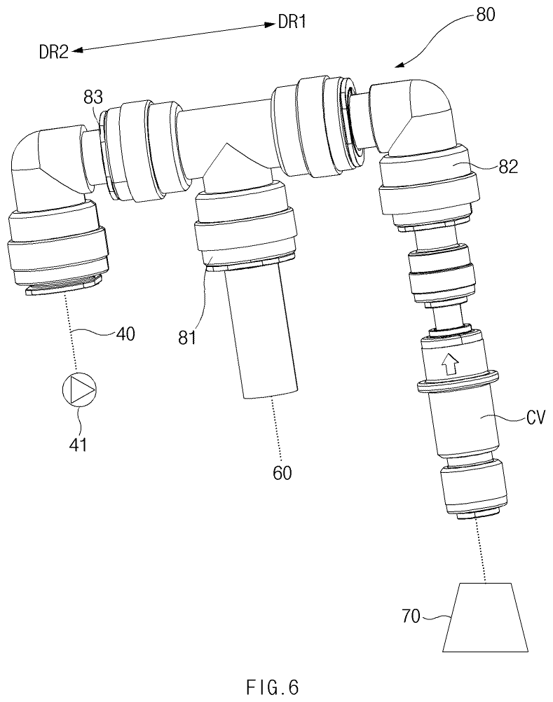

Meanwhile, because there are the plurality of filter modules, the plurality of supply channels, and the plurality of discharge channels, descaling of the filter modules and descaling of the reclaim channels, which will be described later, may be performed one at a time, or may be performed multiple times at a time. Here, the descaling may refer to a process of removing the scale in the filter. In FIGS. 6 to 11 that will be described later, for convenience of description, the descaling of the first filter module 10a and the descaling of a first reclaim channel 50a are illustrated.

### <Circulation Channel 40>

The water treatment system according to an embodiment of the present disclosure may include a circulation channel 40. The circulation channel 40 may be branched from the supply channel 20. The circulation channel 40 may be connected to a descaling part 70 and a connection channel 60, which will be described later.

### <Circulation Pump 41>

The water treatment system according to an embodiment of the present disclosure may include a circulation pump 41. As illustrated in FIG. 1, the circulation pump 41 may be disposed in the circulation channel 40, and may be disposed on an upstream side of a point, at which the circulation channel 40 and the connection channel 60 are connected to each other. The circulation pump 41 may be configured to pump the fluid in the circulation channel 40. As an example, the circulation pump 41 may be configured to pump the descaling material in the circulation channel 40 to the connection channel 60 that will be described later.

### <Reclaim Channel 50>

The water treatment system according to an embodiment of the present disclosure may include a reclaim channel 50. The reclaim channel 50 may be branched from the discharge channel 30. As an example, the reclaim channel 50 may include a first reclaim channel 50a that is branched from the first discharge channel 30a and a second reclaim channel 50b that is branched from the second discharge channel 30b. The reclaim channel 50 may be a channel, through which the above-described reclaimed water is discharged.

A reclaimed water flow detecting sensor may be disposed in the reclaim channel 50. Furthermore, the reclaim channel 50 may be connected to a drain “D”. The drain “D” may include a first drain Da that is connected to the first reclaim channel 50a and a second drain Db that is connected to the second reclaim channel 50b.

### <Reclaim Valve 51>

The water treatment system according to an embodiment of the present disclosure may include a reclaim valve 51. As illustrated in FIG. 1, the reclaim valve 51 may be disposed in the reclaim channel 50, and may be configured to open and close the reclaim channel 50. The reclaim valve 51 may include a first reclaim valve 51a that is disposed in the first reclaim channel 50a and a second reclaim valve 51b that is disposed in the second reclaim channel 50b.

### <Detailed Shape of Reclaim Channel 50>

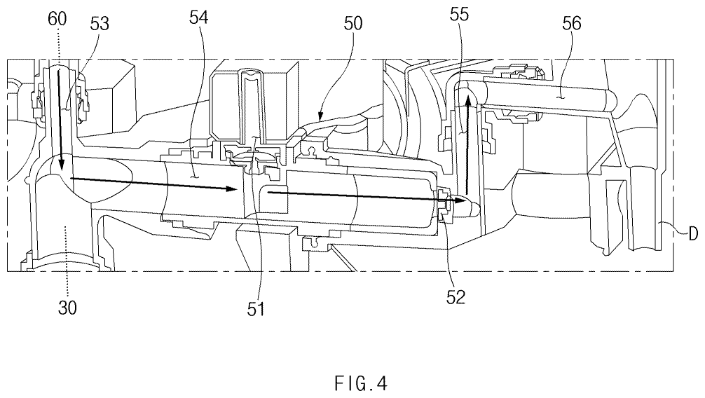

Hereinafter, a detailed shape of the reclaim channel 50 will be described in detail with reference to FIG. 4. FIG. 4 conceptually illustrates a cross section of the reclaim channel. As illustrated in FIG. 4, the reclaim channel 50 may include a first reclaim line 53, a second reclaim line 54, and a third reclaim line 55. The first reclaim line 53 may be located on an upstream side of the reclaim valve 51. The first reclaim line 53 may extend upward, and may be connected to the connection channel 60.

One end of the second reclaim line 54 may be connected to a lower end of the first reclaim line 53. The reclaim valve 51 may be disposed in the second reclaim line 54. Furthermore, the second reclaim line 54 may be communicated with the discharge channel 30.

The third reclaim line 55 may be located on a downstream side of the reclaim valve 51, and may be connected to an opposite end of the second reclaim line 54. The third reclaim line 55 may extend upward. Because the third reclaim line 55 extends upward, the descaling material may be stored in the second reclaim line 54 while the descaling material is filled, starting from a lower side of the third reclaim line 55. As an example, a portion that connects the first to third reclaim lines 53, 54, and 55 may be “U”-shaped.

As illustrated in FIG. 4, the reclaim channel 50 may further include a fourth reclaim line 56. The fourth reclaim line 56 may be connected to an upper end of the third reclaim line 55, and may extend across the third reclaim line 55.

Meanwhile, when a process of injecting the descaling material into the reclaim channel 50 to remove the scale in the reclaim valve 51 is a reclaim channel injection process, in the reclaim channel injection process, the descaling material may be filled up to a reservoir boundary of the third reclaim line 55 and the fourth reclaim line 56.

As illustrated in FIG. 4, the reclaim channel 50 may include a pressure reducing ring 52. The pressure reducing ring 52 may be disposed at a boundary of the second reclaim line 54 and the third reclaim line 55. As an example, a size of an inlet of the pressure reducing ring 52 may be smaller than a size of an outlet thereof. As illustrated in FIG. 1, the pressure reducing ring 52 may include a first pressure reducing ring 52a that is disposed in the first reclaim channel 50a and a second pressure reducing ring 52b that is disposed in the second reclaim channel 50b.

According to the present disclosure, the descaling material may be stored in the reclaim channel 50, and the scale in the reclaim valve 51 and the pressure reducing ring 52 may be directly removed through the descaling material. Accordingly, the scale removing effect may increase.

### <Connection Channel 60>

The water treatment system according to an embodiment of the present disclosure may include a connection channel 60. The connection channel 60 may connect the discharge channel 30 and the circulation channel 40. The connection may be a direct connection or an indirect connection. Furthermore, the connection channel 60 may be connected to a descaling part 70 that will be described later.

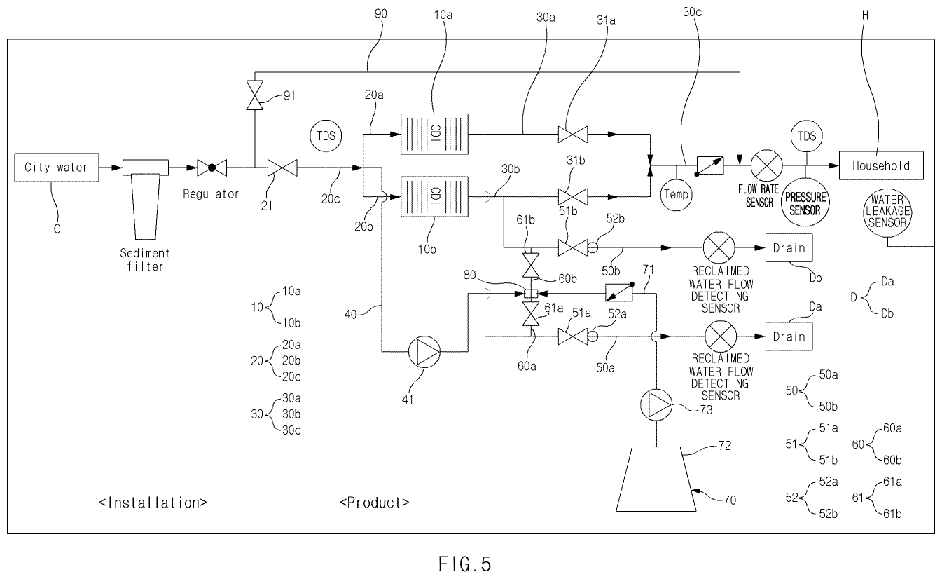

FIG. 5 is a water pipeline diagram of a water treatment system according to another embodiment of the present disclosure. As illustrated in FIG. 5, the connection channel 60 may be branched from the discharge channel 30. Then, as illustrated in FIG. 5, a point, at which the connection channel 60 is branched from the discharge channel 30, and a point, at which the reclaim channel 50 is discharged from the discharge channel 30, may coincide with each other.

As illustrated in FIG. 5, the connection channel 60 may be branched from the reclaim channel 50, and may be connected to the circulation channel 40. Because the reclaim channel 50 is connected to the discharge channel 30, the connection channel 60 may connect the discharge channel 30 and the circulation channel 40. However, the connection channel 60 does not necessarily have to be an independent channel, but may be a part of the circulation channel 40, a part of the reclaim channel 50, or a part of the descaling part 70 that will be described later.

Meanwhile, as illustrated in FIG. 1, the connection channel 60 may include a first connection channel 60a that is connected to the first reclaim channel 50a and a second connection channel 60b that is connected to the second reclaim channel 50b.

### <Connection Valve 61>

The water treatment system according to an embodiment of the present disclosure may include a connection valve 61. As illustrated in FIG. 1, the connection valve 61 may be disposed in the connection channel 60, and may be configured to open and close the connection channel 60. The connection valve 61 may include a first connection valve 61a that is disposed in the first connection channel 60a and a second connection valve 61b that is disposed in the second connection channel 60b.

### <Descaling Part 70>

The water treatment system according to an embodiment of the present disclosure may include a descaling part 70. The descaling part 70 may be connected to the connection channel 60, and may be configured to provide the descaling material for removing the scale to an interior of the connection channel 60. The descaling part 70 may include at least one of citric acid and an electrolytic descaling material, as the descaling material.

The descaling part 70 may include a descaling channel 71, a descaling module 72, and a descaling pump 73. The descaling channel 71 may be connected to the connection channel 60. The descaling module 72 may be connected to a distal end of the descaling channel 71, and may provide the descaling material to the descaling channel 71.

As an example, the descaling module 72 may be a citric acid storage tank. The citric acid storage tank may be a storage tank for storing and discharging the citric acid as the descaling material.

As another example, the descaling module 72 may be a sterilizing water storage tank. The sterilizing water storage tank may be a storage tank for storing and discharging a residual chlorine-based solution as a sterilizing material.

As another example, the descaling module 72 may be an electrolysis sterilization generating module. The electrolysis sterilization generating module may generate and discharge an electrolysis sterilizing material by applying electricity to water. The electrolysis sterilization generating module may include a material generating part that is configured to generate electrolysis sterilizing material by using electricity, an electrolyte storage tank for storing the generated electrolysis sterilizing material, and a source water supply line for supplying the source water.

The descaling pump 73 may be disposed in the descaling channel 71, and may be configured to pump the descaling material provided by the descaling module 72 to the connection channel 60 through the descaling channel 71. In more detail, the descaling pump 73 may pump the descaling material such that the descaling material is introduced into the filter module 10 in a reverse direction. The reverse direction may mean an opposite direction to a forward direction, when a direction, in which the soft water is discharged from the filter module 10, is the forward direction.

For example, the descaling material pumped to the connection channel 60 may be introduced into the filter module 10 through the above-described reclaim channel 50 and the drain channel. This introduction may be an introduction in the reverse direction to the filter module 10.

According to the water treatment system according to an embodiment of the present disclosure, the descaling material may be injected in the reverse direction of the filter module 10 whereby a scale removing effect in the filter module 10 may be improved compared to a case, in which the descaling material is injected only in the forward direction.

### <Fitting Module 80>

The water treatment system according to an embodiment of the present disclosure may further include a fitting module 80. FIG. 6 is a view illustrating the fitting module. The fitting module 80 may connect the circulation channel 40, the connection channel 60, and the descaling part 70. Then, the connection channel 60 may be a separate channel from the fitting module 80, or the connection channel 60 may be a part of the fitting module 80. The circulation channel 40, the descaling part 70, and the reclaim channel 50 connected to the connection channel 60 may be connected to each other through the fitting module 80.

The fitting module 80 may include a first part 81, a second part 82, and a third part 83. The first part 81 extends downward, and may be connected to the reclaim channel 50 through the connection channel 60. Then, as described above, the first part 81 may be connected to a separate connection channel 60, and the connection channel 60 may be a part of the first part 81.

The second part 82 may have a shape that extends from an upper end of the first part 81 in a first direction DR1 and then extends downward. The first direction DR1 may be a direction that crosses a downward direction. The second part 82 may be connected to the descaling part 70. The second part 82 may include a check valve CV that prevents backflow of the descaling material.

The third part 83 extends from an upper end of the first part 81 in a second direction DR2, and may be connected to the circulation channel 40. The second direction DR2 may be an opposite direction to the first direction DR1.

In the water treatment system according to an embodiment of the present disclosure, the descaling part 70, the circulation channel 40, and the reclaim channel 50 may be connected to each other through the fitting module 80. Accordingly, by coupling the fitting module 80 of the water treatment system according to an embodiment of the present disclosure to the water treatment system, in which the descaling part, the circulation channel, and the reclaim channel are not connected to each other, an effect of increasing the scale removing effect of the water treatment system, which is provided by the water treatment system according to an embodiment of the present disclosure may be conveniently derived.

### <Bypass Channel 90>

As illustrated in FIG. 1, the water treatment system according to an embodiment of the present disclosure may include a bypass channel 90. The bypass channel 90 may be a channel for supplying the source water to the user when the soft water that has passed through the filter module 10 cannot be supplied to the demand source “H”. The bypass channel 90 may connect one point that is located on an upstream side of the supply valve 21 with respect to a direction, in which the water flows in the supply channel 20 and one point in the discharge channel 30, which is located on a downstream side of the discharge valve 31 with respect to a direction, in which the water flows in the discharge channel 30. Accordingly, when the supply valve 21 and the discharge valve 31 are locked and the water cannot flow through the filter module 10, the water may be guided to the bypass channel 90.

The bypass valve 91 may be disposed in the bypass channel 90 to open and close the bypass channel 90. In a situation, in which the soft water may be supplied to the demand source “H”, there is no need for the water to flow through the bypass channel 90, and thus, the bypass valve 91 may be closed. However, as an example, in a process of descaling the filter module 10, the soft water cannot be supplied to the demand source “H”, and thus, the source water may need to be supplied through the bypass channel 90. In this case, the bypass valve 91 may be opened.

### <Controller>

The controller may be configured to control the supply valve 21, the discharge valve 31, the circulation pump 41, the reclaim valve 51, the connection valve 61, and the descaling part 70. Controlling the descaling part 70 may mean controlling the descaling pump 73 and the descaling module 72.

The controller may include a processor and memory. The processor may include a microprocessor, such as a field programmable gate array (FPGA), an application specific integrated circuit (ASIC), or a central processing unit (CPU).

The memory may store control instructions that are the basis for the processor to generate instructions for determining whether the valves are open or closed and whether the pump is operated. The memory may be a data store, such as a hard disk drive (HDD), a solid state drive (SSD), a volatile medium, or a non-volatile medium.

### Descaling of Filter Module

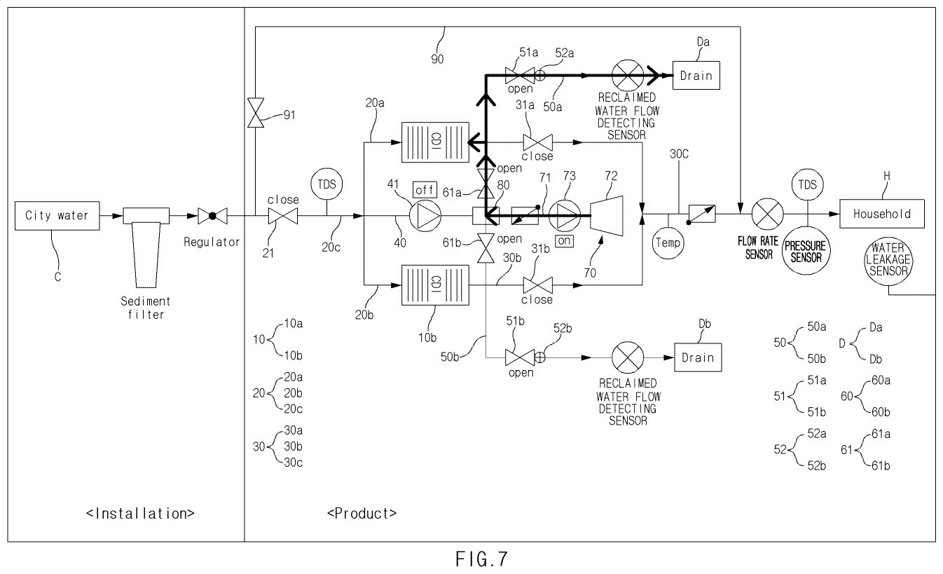

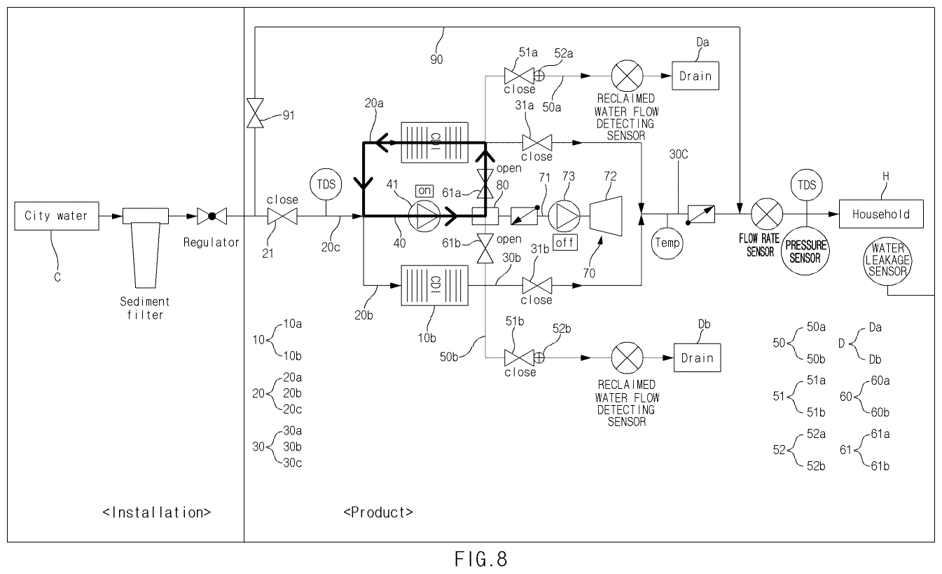

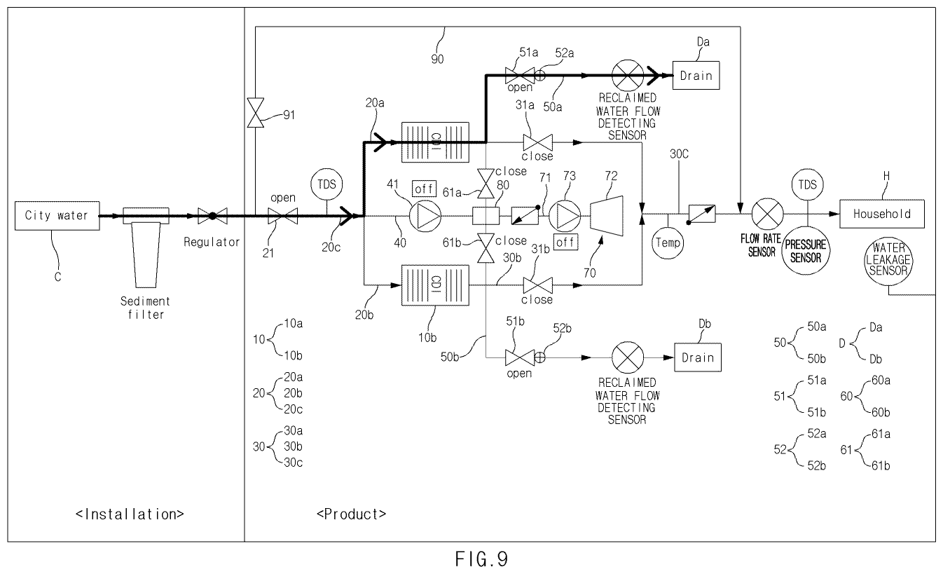

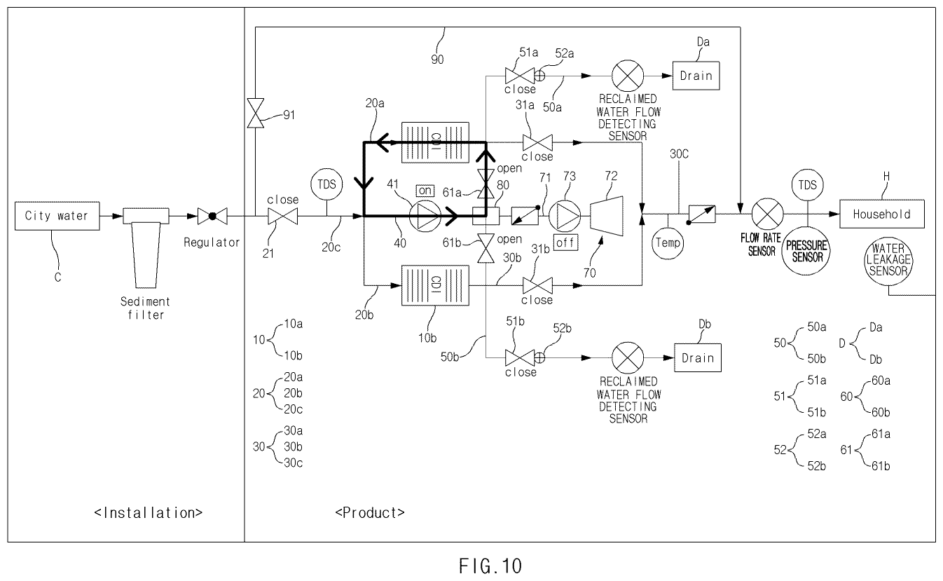

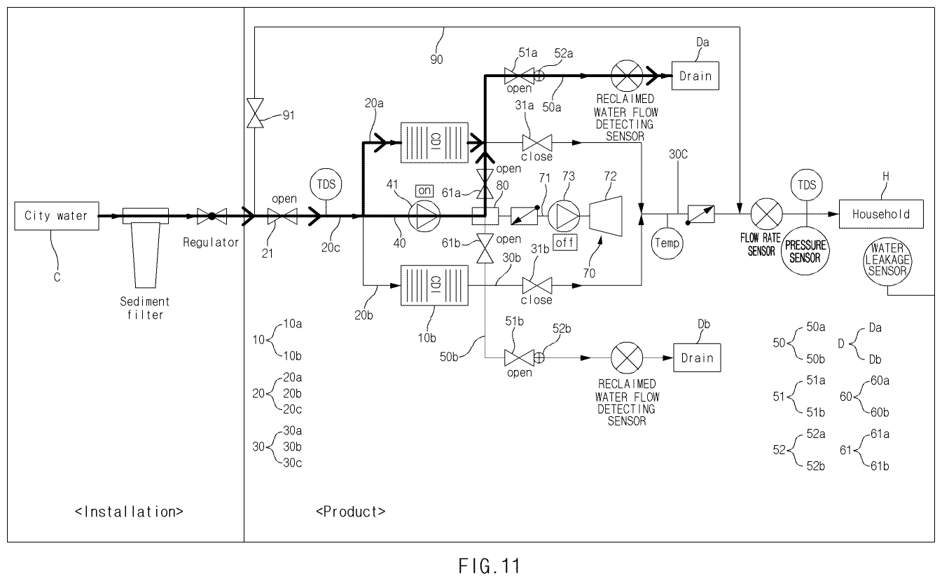

Hereinafter, a progress of descaling the filter module 10 will be described in detail based on operation states of the valve and the pump. The descaling of the filter module may include a filter module injection process, a circulation process, and a flushing process. FIG. 7 is a view illustrating the filter module injection process. FIG. 8 is a view illustrating the circulation process. FIG. 9 is a view illustrating the module flushing process. FIG. 10 is a view illustrating the pump flushing process. FIG. 11 is a view illustrating a discharge process.

In FIGS. 7 and 8, a thick line may mean movement of the descaling material, and in FIGS. 9, 10, and 11, a thick line may mean movement of the source water. The descaling of the filter module 10 may be understood as a process of changing from a state of FIG. 7 to a state of FIG. 11 via states of FIG. 8, FIG. 9, and FIG. 10.

For convenience of description, the drawings only illustrate a process of descaling the first filter module 10a, among the filter modules 10, but when necessary, only the second filter module 10b may be descaled, and the first filter module 10a and the second filter module 10b may be descaled simultaneously.

### <Filter Module Injection Process>

Hereinafter, the filter module injection process will be described in detail with reference to FIG. 7 and Table 1. The filter module injection process may be a process of injecting the descaling material into the filter module 10 to remove the scale in the filter module 10. In more detail, the filter module injection process may be a process of injecting the descaling material into the filter module 10 in the reverse direction.

TABLE 1
Filter Module Injection Process

| Reclaim | Supply | Discharge | Connection | Descaling | Circulation |
|---|---|---|---|---|---|
| valve | valve | valve | valve | part | pump |
| Opened | Closed | Closed | Opened | On | Off |

In the filter module injection process, the controller may control the reclaim valve 51 so that the reclaim channel 50 is opened. Furthermore, the controller may control the supply valve 21 so that the supply channel 20 is closed. Furthermore, the controller may control the discharge valve 31 so that the discharge channel 30 is closed. Furthermore, the controller may control the connection valve 61 so that the connection channel 60 is opened. Furthermore, the controller may operate the descaling part 70 to provide the descaling material to the filter module 10 through the connection channel 60 and the discharge channel 30. Meanwhile, the operation of the descaling part 70 may be later than the control of the reclaim valve 51, the supply valve 21, the discharge valve 31, and the connection valve 61. As an example, in the filter module injection process, the descaling part 70 may provide the descaling material when the reclaim valve 51 opens the reclaim channel 50. Furthermore, the descaling part 70 may provide the descaling material when the supply valve 21 closes the supply channel 20 and the discharge valve 31 closes the discharge channel 30.

### <Circulation Process>

Hereinafter, the circulation process will be described in detail with reference to FIG. 8 and Table 2. The circulation process may be a process of removing the scale in the filter module 10 by repeatedly circulating the descaling material introduced into the filter module 10 to the filter module 10 through the circulation channel 40.

TABLE 2
Circulation Process

| Reclaim | Supply | Discharge | Connection | Descaling | Circulation |
|---|---|---|---|---|---|
| valve | valve | valve | valve | part | pump |
| Closed | Closed | Closed | Opened | Off | On |

In the circulation process, the controller may control the reclaim valve 51 so that the reclaim channel 50 is closed. Furthermore, the controller may control the supply valve 21 so that the supply channel 20 is closed. Furthermore, the controller may control the discharge valve 31 so that the discharge channel 30 is closed. Furthermore, the controller may control the connection valve 61 so that the connection channel 60 is opened. Furthermore, the controller may stop the operation of the descaling part 70. Furthermore, the controller may operate the circulation pump 41 to pump the descaling material in the circulation channel 40 and thus circulate the descaling material to the filter module 10. The operation of the circulation pump 41 may be later than the control of the above-described reclaim valve 51, the supply valve 21, the discharge valve 31, and the connection valve 61 and the stop of the operation of the descaling part 70.

### <Module Flushing Process>

Hereinafter, the module flushing process will be described in detail with reference to FIG. 9 and Table 3. The module flushing process may be a process of discharging the source water introduced through the supply channel 20 via the filter module 10, through the reclaim channel 50. Through the module flushing process, the descaling material in the interior of the filter module 10 may also be discharged together through the reclaim channel 50.

TABLE 3
Module Flushing Process

| Reclaim | Supply | Discharge | Connection | Descaling | Circulation |
|---|---|---|---|---|---|
| valve | valve | valve | valve | part | pump |
| Opened | Opened | Closed | Closed | Off | Off |

In the module flushing process, the controller may control the reclaim valve 51 so that the reclaim channel 50 is opened. Furthermore, the controller may control the supply valve 21 so that the supply channel 20 is opened. Furthermore, the controller may control the discharge valve 31 so that the discharge channel 30 is closed. Furthermore, the controller may control the connection valve 61 so that the connection channel 60 is closed. Furthermore, the controller may stop the operation of the circulation pump 41. Meanwhile, the opening of the supply channel 20 may later than the closing of the connection channel 60.

### <Pump Flushing Process>

Hereinafter, the pump flushing process will be described in detail with reference to FIG. 10 and Table 4. The pump flushing process may be a process for reducing a concentration of the descaling material in the circulation channel 40 by circulating the source water introduced through the supply channel 20. The descaling material in an interior of the circulation channel 40 may be diluted through the pump flushing process.

TABLE 4
Pump Flushing Process

| Reclaim | Supply | Discharge | Connection | Descaling | Circulation |
|---|---|---|---|---|---|
| valve | valve | valve | valve | part | pump |
| Closed | Closed | Closed | Opened | Off | On |

In the pump flushing process, the controller may control the reclaim valve 51 so that the reclaim channel 50 is closed. Furthermore, the controller may control the supply valve 21 so that the supply channel 20 is closed. Furthermore, the controller may control the discharge valve 31 so that the discharge channel 30 is closed. Furthermore, the controller may control the connection valve 61 so that the connection channel 60 is opened. Furthermore, the controller may operate the circulation pump 41.

Meanwhile, after the pump flushing process is completed, the discharge process may be performed. Hereinafter, the discharge process will be described in detail with reference to FIG. 11 and Table 5. In the discharge process, the source water may be introduced once again and the descaling material may be discharged together with the source water through the reclaim channel 50.

TABLE 5
Discharge Process

| Reclaim | Supply | Discharge | Connection | Descaling | Circulation |
|---|---|---|---|---|---|
| valve | valve | valve | valve | part | pump |
| Opened | Opened | Closed | Opened | Off | On |

In the discharge process, the controller may control the reclaim valve 51 so that the reclaim channel 50 is opened. Furthermore, the controller may control the supply valve 21 so that the supply channel 20 is opened. Furthermore, the controller may control the discharge valve 31 so that the discharge channel 30 is closed. Furthermore, the controller may control the connection valve 61 so that the connection channel 60 is opened. Furthermore, the controller may operate the circulation pump 41. The module flushing process, the pump flushing process and the discharge process may be performed multiple times. For example, the module flushing process, the pump flushing process, and the discharge process may be performed twice. This may mean going through the module flushing process, the pump flushing process, and the discharge process, and then going through the module flushing process, the pump flushing process, and the discharge process again.

### Descaling of Reclaim Valve

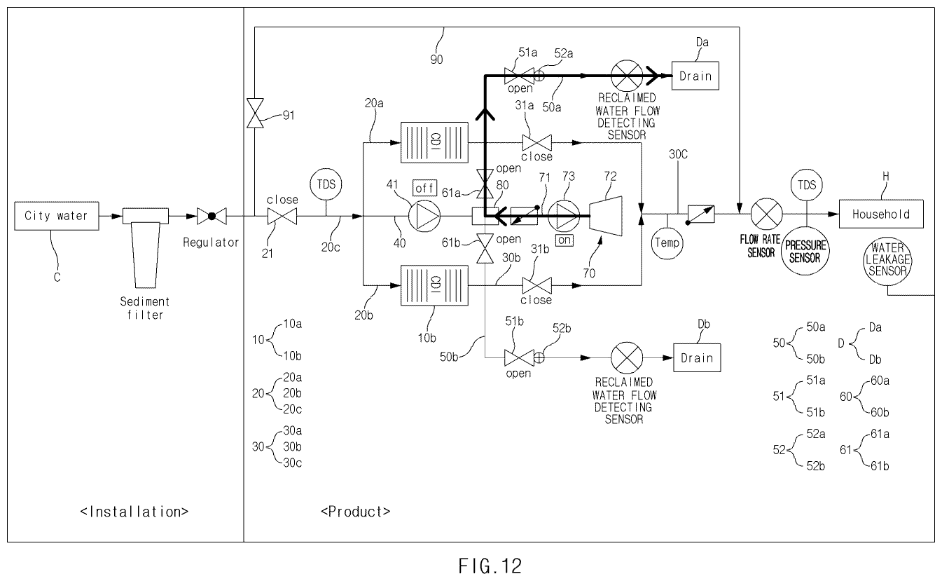

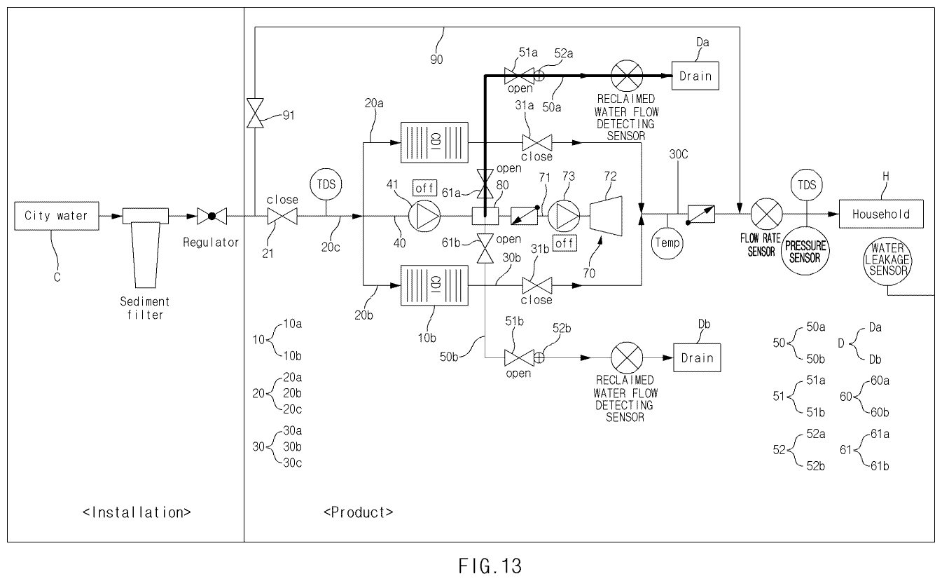

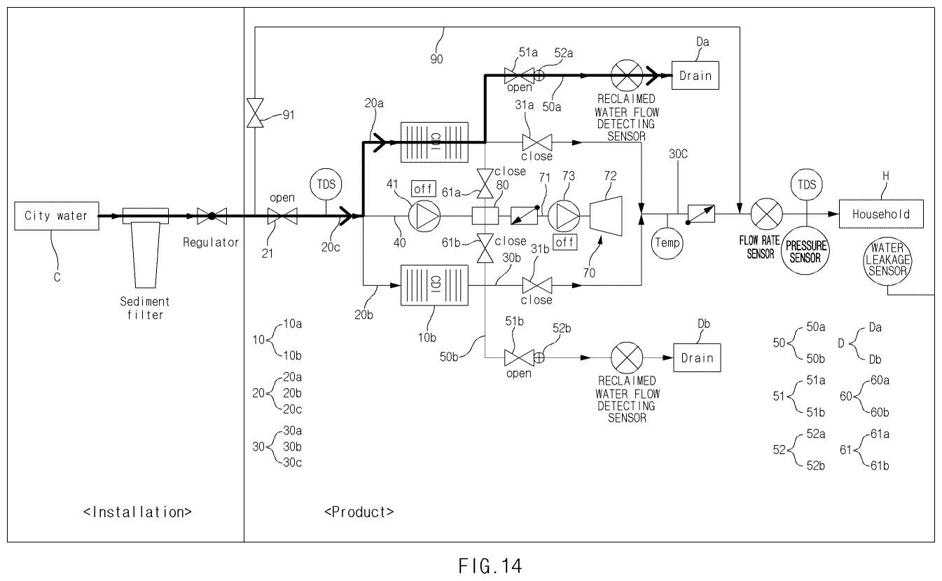

Hereinafter, a progress of descaling the reclaim valve will be described in detail based on the operation states of the valves and the pump. The descaling of the reclaim valve may include a reclaim channel injection process, a standby process, and a flushing process. FIG. 12 is a view illustrating the reclaim channel injection process. FIG. 13 is a view illustrating the standby process. FIG. 14 is a view illustrating the flushing process. Thick lines in FIGS. 12 and 13 may mean movement of the descaling material, and a thick line in FIG. 14 may mean movement of the source water. That is, the descaling of the reclaim valve may be understood as a process of changing from the states of FIG. 12 to FIG. 13 to the state of FIG. 14.

### <Reclaim Channel Injection Process>

Hereinafter, the reclaim channel injection process will be described in detail with reference to FIG. 12 and Table 6. The reclaim channel injection process may be a process of injecting the descaling material into the reclaim channel 50 to remove the scale in the reclaim valve 51.

TABLE 6
Reclaim Channel Injection Process

| Reclaim | Supply | Discharge | Connection | Descaling | Circulation |
|---|---|---|---|---|---|
| valve | valve | valve | valve | part | pump |
| Opened | Closed | Closed | Opened | On | Off |

In the reclaim channel injection process, the controller may control the reclaim valve 51 so that the reclaim channel 50 is opened. Furthermore, the controller may control the supply valve 21 so that the supply channel 20 is closed. Furthermore, the controller may control the discharge valve 31 so that the discharge channel 30 is closed. Furthermore, the controller may control the connection valve 61 so that the connection channel 60 is opened. Furthermore, the controller may operate the descaling part 70 and provide descaling material to the reclaim channel 50 via the connection channel 60. In the reclaim channel injection process, the descaling material may be filled up to the reservoir boundary. Meanwhile, in the reclaim channel injection process, the operation of the descaling part 70 may be later than the control of the reclaim valve 51, the supply valve 21, the discharge valve 31, and the connection valve 61. As an example, in the reclaim channel injection process, the descaling part 70 may provide the descaling material when the reclaim valve 51 opens the reclaim channel 50. Furthermore, as an example, in the reclaim channel injection process, the descaling part 70 provides the descaling material when the supply valve 21 closes the supply channel 20 and the discharge valve 31 closes the discharge channel 30.

### <Standby Process>

Hereinafter, the standby process will be described in detail with reference to FIG. 13 and Table 7. The standby process may be a process of stopping the operation of the descaling part 70 and waiting for a while after injecting the descaling material into the reclaim channel 50.

TABLE 7
Standby Process

| Reclaim | Supply | Discharge | Connection | Descaling | Circulation |
|---|---|---|---|---|---|
| valve | valve | valve | valve | part | pump |
| Opened | Closed | Closed | Opened | Off | Off |

In the standby process, the controller may control the reclaim valve 51 so that the reclaim channel 50 is opened. Furthermore, the controller may control the supply valve 21 so that the supply channel 20 is closed. Furthermore, the controller may control the discharge valve 31 so that the discharge channel 30 is closed. Furthermore, the controller may control the connection valve 61 so that the connection channel 60 is opened. Furthermore, the controller may stop the operation of the descaling part 70. The descaling material stored in the reclaim channel 50 may remove the scale in the reclaim valve 51 and pressure reducing ring 52 in the standby process. <Flushing Process>

Hereinafter, the flushing process will be described in detail with reference to FIG. 14. The flushing process may be a process of discharging the source water introduced through the supply channel 20 through the reclaim channel 50. Through the flushing process, the descaling material in an interior of the reclaim channel 50 may be discharged together with the source water. Because the flushing process may correspond to the module flushing process described above, a detailed description thereof will be omitted.

The above description is a simple exemplary description of the technical spirits of the present disclosure, and an ordinary person in the art, to which the present disclosure pertains, may make various corrections and modifications without departing from the essential characteristics of the present disclosure. Therefore, the embodiments disclosed in the present disclosure are not for limiting the technical spirits of the present disclosure but for describing them, and the scope of the technical spirits of the present disclosure is not limited by the embodiments. The protection scope of the present disclosure should be construed by the following claims, and all the technical spirits in the equivalent range should be construed as being included in the scope of the present disclosure.

1. A water treatment system for removing at least some of ionic materials contained in source water and providing soft water containing less ionic materials than the source water to a demand source, the water treatment system comprising:
a filter module configured to remove at least some of the ionic materials contained in the source water based on an electrical force, and discharge the soft water;
a supply channel configured to supply the source water to the filter module;
a discharge channel configured to guide the soft water discharged from the filter module to the demand source;
a circulation channel branched from the supply channel;
a reclaim channel branched from the discharge channel;
a connection channel connecting the discharge channel and the circulation channel; and
a descaling part connected to the connection channel, and configured to provide a descaling material for removing scale to an interior of connection channel.

2. The water treatment system of claim 1, wherein the descaling part includes:
a descaling channel connected to the connection channel;
a descaling module connected to a distal end of the descaling channel, and configured to provide the descaling material to the descaling channel; and
a descaling pump disposed in the descaling channel, and configured to pump the descaling material provided by the descaling module, to the connection channel through the descaling channel.

3. The water treatment system of claim 1, further comprising:
a reclaim valve disposed in the reclaim channel, and configured to open and close the reclaim channel,
wherein when a process of injecting the descaling material to the filter module to remove the scale in the filter module is a filter module injection process,
in the filter module injection process,
the descaling part provides the descaling material when the reclaim valve opens the reclaim channel.

4. The water treatment system of claim 1, further comprising:
a supply valve disposed in the supply channel, disposed on an upstream side of a point, at which the circulation channel is branched from the supply channel, and configured to open and close the supply channel; and
a discharge valve disposed in the discharge channel, disposed on a downstream side of a point, at which the reclaim channel is branched from the discharge channel, and configured to open and close the discharge channel,
wherein the descaling part provides the descaling material when the supply valve closes the supply channel and the discharge valve closes the discharge channel.

5. The water treatment system of claim 1, further comprising:
a circulation pump disposed in the circulation channel, disposed on an upstream side of a point, at which the circulation channel and the connection channel are connected to each other, and configured to pump a fluid in the circulation channel to the connection channel.

6. The water treatment system of claim 5, wherein when a process of cleaning the filter module by circulating the descaling material is a circulation process,
in the circulation process,
the descaling part stops providing the descaling material, and
the circulation pump pumps the descaling material in the circulation channel.

7. The water treatment system of claim 1, further comprising:
a connection valve disposed in the connection channel, and configured to open and close the connection channel,
wherein when a process of discharging the source water introduced through the supply channel, through the reclaim channel via the filter module is a module flushing process,
in the module flushing process,
the connection valve closes the connection channel.

8. The water treatment system of claim 7, further comprising:
a circulation pump disposed in the circulation channel, disposed on an upstream side of a point, at which the circulation channel and the connection channel are connected to each other, and configured to pump the fluid in the circulation channel to the connection channel,
wherein when a process of flushing the circulation pump after the module flushing process is a pump flushing process,
in the pump flushing process,
the connection valve opens the connection channel, and
the circulation pump pumps the fluid in the circulation channel to the connection channel.

9. The water treatment system of claim 8, further comprising:
a supply valve disposed in the supply channel, disposed on an upstream side of a point, at which the circulation channel is branched from the supply channel, and configured to open and close the supply channel; and
a discharge valve disposed in the discharge channel, disposed on a downstream side of a point, at which the reclaim channel is branched from the discharge channel, and configured to open and close the discharge channel,
wherein when a process of introducing the source water into the circulation channel and discharging the source water to the reclaim channel after the pump flushing process is a discharge process,
in the discharge process,
the supply valve opens the supply channel, and
the discharge valve opens the discharge channel.

10. The water treatment system of claim 1, further comprising:
a reclaim valve disposed in the reclaim channel, and configured to open and close the reclaim channel,
wherein when a process of injecting the descaling material to the reclaim channel to remove scale in the reclaim valve is a reclaim channel injection process,
in the reclaim channel injection process,
the descaling part provides the descaling material when the reclaim valve opens the reclaim channel.

11. The water treatment system of claim 10, wherein the reclaim channel includes:
a first reclaim line located on an upstream side of the reclaim valve, extending upward, and connected to the connection channel;
a second reclaim line, one end of which is connected to a lower end of the first reclaim line, and in which the reclaim valve is disposed; and
a third reclaim line located on a downstream side of the reclaim valve, connected to an opposite end of the second reclaim line, and extending upward.

12. The water treatment system of claim 11, wherein the reclaim channel further includes:
a pressure reducing ring disposed at a boundary of the second reclaim line and the third reclaim line, and
wherein a size of an inlet of the pressure reducing ring is smaller than a size of an outlet thereof.

13. The water treatment system of claim 11, wherein the reclaim channel further includes:
a fourth reclaim line connected to an upper end of the third reclaim line, and extending to cross the third reclaim line,
wherein in the reclaim channel injection process,
the descaling material is filled up to a reservoir boundary being a boundary of the third reclaim line and the fourth reclaim line.

14. The water treatment system of claim 1, further comprising:
a fitting module connecting the circulation channel, the connection channel, and the descaling part,
wherein the fitting module includes:
a first part extending downward, and connected to the connection channel;
a second part having a shape extending from an upper end of the first part in a first direction being a direction crossing a downward direction and then extending downward, and connected to the descaling part; and
a third part extending from the upper end of the first part in a second direction being an opposite direction to the first direction, and connected to the circulation channel.

15. The water treatment system of claim 1, further comprising:
a reclaim valve disposed in the reclaim channel, and configured to open and close the reclaim channel;
a supply valve disposed in the supply channel, disposed on an upstream side of a point, at which the circulation channel is branched from the supply channel, and configured to open and close the supply channel;
a discharge valve disposed in the discharge channel, disposed on a downstream side of a point, at which the reclaim channel is branched from the discharge channel, and configured to open and close the discharge channel;
a connection valve disposed in the connection channel, and configured to open and close the connection channel;
a circulation pump disposed in the circulation channel, disposed on an upstream side of a point, at which the circulation channel and the connection channel are connected to each other, and configured to pump the fluid in the circulation channel to the connection channel; and
a controller configured to control the descaling part, the reclaim valve, the supply valve, the discharge valve, the connection valve, and the circulation pump.

16. The water treatment system of claim 15, wherein when a process of injecting the descaling material into the filter module to remove the scale in the filter module is a filter module injection process,
in the filter module injection process,
the controller is configured to:
control the reclaim valve to open the reclaim channel;
control the supply valve to close the supply channel;
control the discharge valve to close the discharge channel;
control the connection valve to open the connection channel; and
operate the descaling part to provide the descaling material to the filter module via the connection channel and the discharge channel.

17. The water treatment system of claim 15, wherein when a process of removing the scale in the filter module by circulating the descaling material to the filter module is a circulation process,
in the circulation process,
the controller is configured to:
control the reclaim valve to close the reclaim channel;
control the supply valve to close the supply channel;
control the discharge valve to close the discharge channel;
control the connection valve to open the connection channel;
stop an operation of the descaling part; and
circulate the descaling material to the filter module by operating the circulation pump to pump the descaling material in the circulation channel.

18. The water treatment system of claim 15, wherein when a process of discharging the source water introduced through the supply module, through the reclaim channel via the filter module is a module flushing process,
in the module flushing process,
the controller is configured to:
control the reclaim valve to open the reclaim channel;
control the supply valve to open the supply channel;
control the discharge valve to close the discharge channel;
control the connection valve to close the connection channel;
stop an operation of the circulation pump; and
discharge the source water introduced through the supply channel, via the filter module, the discharge channel, and the reclaim channel.

19. The water treatment system of claim 15, wherein when a process of injecting the descaling material to the reclaim channel to remove the scale in the reclaim valve is a reclaim channel injection process,
in the reclaim channel injection process,
the controller is configured to:
control the reclaim valve to open the reclaim channel;
control the supply valve to close the supply channel;
control the discharge valve to close the discharge channel;
control the connection valve to open the connection channel; and
operate the descaling part and provide the descaling material to the reclaim channel via the connection channel.

20. A water treatment system for removing at least some of ionic materials contained in source water and providing soft water containing less ionic materials than the source water to a demand source, the water treatment system comprising:
a filter module configured to remove at least some of the ionic materials contained in the source water based on an electrical force, and discharge the soft water;
a supply channel configured to supply the source water to the filter module;
a discharge channel configured to guide the soft water discharged from the filter module to the demand source;
a reclaim channel branched from the discharge channel; and
a descaling part connected to the reclaim channel, and configured to provide a descaling material for removing scale to an interior of the reclaim channel.

21-22. (canceled)
